(19) United States
(12) Patent Application Publication
(10) Pub. No.: US 2014/0306327 A1
(43) Pub. Date: Oct. 16, 2014

(54) SEMICONDUCTOR DEVICE AND METHOD OF MANUFACTURING THEREOF

(71) Applicant: INFINEON TECHNOLOGIES AG, Neubiberg (DE)

(72) Inventors: Hans-Joachim SCHULZE, Taufkirchen (DE); Johannes BAUMGARTL, Riegersdorf (AT); Gerald LACKNER, Arnoldstein (AT); Anton MAUDER, Kolbermoor (DE); Francisco Javier SANTOS RODRIGUEZ, Villach (AT)

(73) Assignee: Infineon Technologies AG, Neubiberg (DE)

(21) Appl. No.: 13/862,398

(22) Filed: Apr. 13, 2013

(51) Int. Cl. H01L 21/52; H01L 23/053; H01L 21/78; H01L 23/043

(52) U.S. Cl. CPC H01L 21/52; H01L 23/043; H01L 23/053; H01L 21/78
USPC 257/666; 257/690; 257/685; 438/106; 438/113

(57) ABSTRACT

A semiconductor device includes a device carrier and a semiconductor chip attached to the device carrier. Further, the semiconductor device includes a lid having a recess. The lid includes a semiconductor material and is attached to the device carrier such that the semiconductor chip is accommodated in the recess.

### BACKGROUND

Semiconductor device manufacturers are constantly striving to increase the versatility and performance of their products, while decreasing their cost of manufacture. An important aspect in the manufacture of semiconductor devices is packaging the semiconductor chips. As those skilled in the art are aware, integrated circuits are fabricated on wafers, which are then singulated to produce semiconductor chips. One or more semiconductor chips are placed in a package to protect them from environmental and physical impact. Packaging also involves electrically coupling semiconductor chip electrodes to external terminals of the semiconductor device. Packaging methods providing high performance devices at low expenses are desirable.

### BRIEF DESCRIPTION OF THE DRAWINGS

The accompanying drawings are included to provide a further understanding of embodiments and are incorporated in and constitute a part of this specification. The drawings illustrate embodiments and together with the description serve to explain principles of embodiments. Other embodiments and many of the intended advantages of embodiments will be readily appreciated as they become better understood by reference to the following detailed description. The elements of the drawings are not necessarily to scale relative to each other. Like reference numerals designate corresponding similar parts.

FIG. 1 schematically illustrates a cross-sectional view of an exemplary semiconductor device.

FIGS. 2A-2J schematically illustrate cross-sectional views of an exemplary process of a method of manufacturing a semiconductor device.

FIGS. 3A-3B schematically illustrate cross-sectional views of an exemplary process of a method of manufacturing a semiconductor device.

FIGS. 4A-4B schematically illustrate cross-sectional views of an exemplary process of a method of manufacturing a semiconductor device.

FIG. 5 schematically illustrates a cross-sectional view of an exemplary semiconductor device.

FIG. 6 schematically illustrates a cross-sectional view of an exemplary semiconductor device.

FIG. 7 schematically illustrates a cross-sectional view of an exemplary semiconductor device.

FIGS. 8A-8E schematically illustrate cross-sectional views of an exemplary process of a method of manufacturing a semiconductor device.

FIG. 9 schematically illustrates a cross-sectional view of an exemplary semiconductor device.

FIGS. 10A-10B are perspective views of an exemplary process of a method of manufacturing a semiconductor devices on wafer level.

### DETAILED DESCRIPTION

In the following detailed description, reference is made to the accompanying drawings, which form a part thereof, and in which is shown by way of illustration specific embodiments in which the invention may be practiced. In this regard, directional terminology, such as “top”, “bottom”, “left”, “right”, “upper”, “lower” etc., is used with reference to the orientation of the Figure(s) being described. Because components of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

It is to be understood that the features of the various exemplary embodiments described herein may be combined with each other, unless specifically noted otherwise or unless technically restricted.

As employed in this specification, the terms “bonded”, “attached”, “connected”, “coupled” and/or “electrically coupled” are not meant to mean that the elements must directly be contacted together; intervening elements or layers may be provided between the “bonded”, “attached”, “connected”, “coupled” and/or “electrically coupled” elements, respectively.

The semiconductor devices described below contain one or more semiconductor chips. The semiconductor chips may be manufactured by different technologies and may include, for example, integrated electrical, electro-optical or electro-mechanical circuits and/or passives.

The semiconductor chips may comprise integrated circuits such as, e.g., logic integrated circuits, control circuits, microprocessors, memory devices, power devices, etc.

In particular, semiconductor chips having a vertical structure may be involved, that is to say that the semiconductor chips may be fabricated in such a way that electric currents can flow in a direction perpendicular to the main faces of the semiconductor chips. A semiconductor chip having a vertical structure has electrodes on its two main faces, that is to say on its top side and bottom side (the bottom side is also referred to as backside herein).

The semiconductor chip(s) may, for example, be power semiconductor chip(s). Power semiconductor chips may have a vertical structure. The vertical power semiconductor chip(s) may, for example, be configured as power MOSFETs (Metal Oxide Semiconductor Field Effect Transistors), IGBTs (Insulated Gate Bipolar Transistors), JFETs (Junction Gate Field Effect Transistors), power bipolar transistors or power diodes. By way of example, the source electrode and gate electrode of a power MOSFET may be situated on a front side main face, while the drain electrode of the power MOSFET may be arranged on the backside main face.

The semiconductor chips need not be manufactured from specific semiconductor material, for example Si, SiC, SiGe, GaAs, GaN, and, furthermore, may contain inorganic and/or organic materials that are not semiconductors, such as for example insulators, plastics or metals.

The semiconductor chips may have electrodes which allow electrical contact to be made with the integrated circuits or power devices included in the semiconductor chips. The electrodes may include one or more metal layers which are applied to the semiconductor material of the semiconductor chips. The metal layers may be manufactured with any desired geometric shape and any desired material composition. The metal layers may, for example, be in the form of a layer or land covering an area. By way of example, any desired metal capable of forming a solder bond or diffusion solder bond, for example Cu, Ni, NiSn, Au, Ag, Pt, Pd, In, Sn, and an alloy of one or more of these metals may be used as the material. The metal layers need not be homogenous or manufactured from just one material, that is to say various compositions and concentrations of the materials contained in the metal layers are possible.

Semiconductor devices described herein may comprise device carriers. One or more semiconductor chips are mounted on a device carrier. In one embodiment, the device carrier may comprise or be made of a semiconductor material, e.g. silicon. In some embodiments, the device carrier may comprise a semiconductor material which may have at least partially a metal layer on at least one of the main surfaces. In some embodiments, the device carrier may comprise a semiconductor material which may have at least partially an electrically insulating layer on at least one of the main surfaces, the insulating layer may comprise e. g. one or more of silicon dioxide, silicon nitride, aluminum oxide, etc.

In other embodiments, the device carrier may be a metal plate or sheet such as, e.g., a die pad of a leadframe. The metal plate or sheet may be made of any metal or metal alloy, e.g. copper or copper alloy. In other embodiments, the device carrier may be made of an insulating layer of an organic or inorganic material, e.g. plastics or ceramics. For instance, the device carrier may comprise a layer of plastics coated with a metal layer. Such device carrier may e.g. be a single-layer PCB (Printed Circuit Board) or a multi-layer PCB. The PCB may have at least one insulating layer and a structured metal foil layer attached to the insulating layer. The insulating layer is typically made on the basis of epoxy resin, polytetrafluoroethylene, aramid fibers or carbon fibers and may include one or more reinforcing elements such as fiber mats, for example glass or carbon fibers. In other embodiments, the device carrier may comprise a plate of ceramics coated with a metal layer, e.g. a metal bonded ceramics substrate. By way of example, the device carrier may be a DCB (direct copper bonded) ceramics substrate.

Semiconductor devices described herein comprise lids. A lid as referred to herein may comprise or may be made of a semiconductor material. By way of example, the lid may be made of a bulk semiconductor material. The lid may, e.g., be a semiconductor chip having a recess, e.g. a Si, SiC, SiGe, GaAs, GaN chip having a recess.

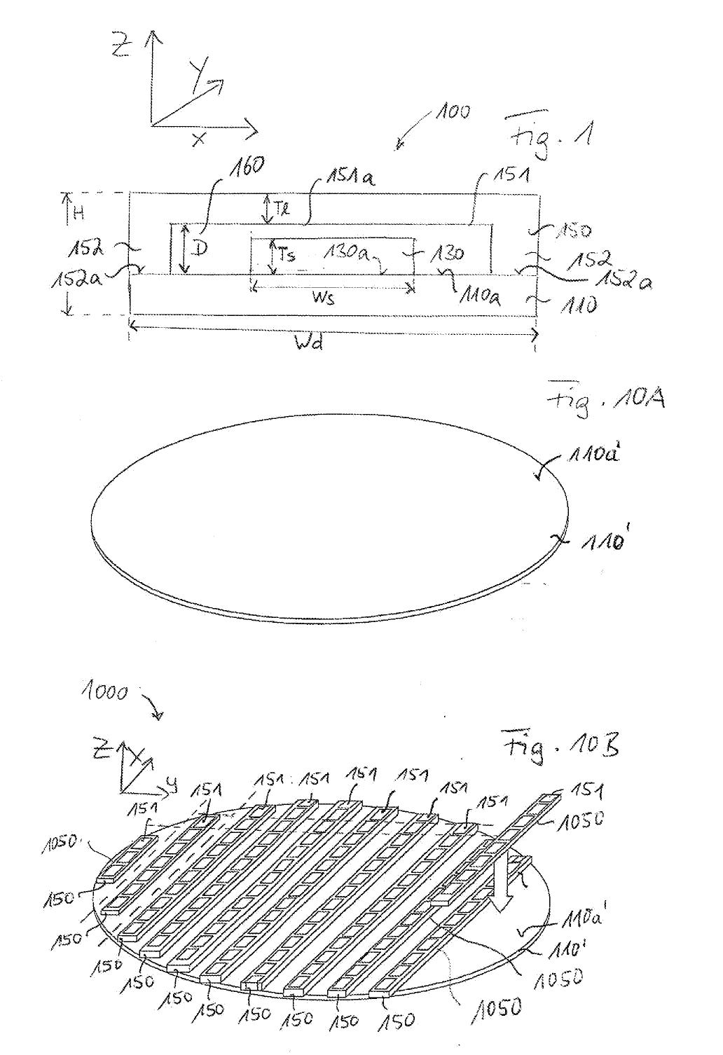

FIG. 1 illustrates an exemplary semiconductor device 100. The semiconductor device 100 comprises a device carrier 110, a semiconductor chip 130 and a lid 150. The semiconductor chip 130 may be attached to an upper surface 110a of the device carrier 110 the device carrier 110. The lid 150 has a recess 151 in which the semiconductor chip 130 is accommodated. Further, the lid 150 is attached to the device carrier 110. That way, the lid 150 and the device carrier 110 may define a cavity 160, in which the semiconductor chip 130 is contained.

More specifically, the recess 151 formed in the lid 150 may define a side wall 152 of the lid 150 which partly or completely surrounds the recess 150. The side wall 152 may comprise a bottom surface 152a which is mounted on the device carrier 110. As will be explained by way of example in more detail further below, the bottom surface 152a of the side wall 152 of the lid 150 may be bonded to the upper surface 110a of the device carrier 110 by an adhesive layer, an oxide bonding layer (not shown in FIG. 1), etc.

The lid 150 may comprise or be made of a semiconductor material. More specifically, the lid 150 may be a bulk semi-conductor part, in which the recess 151 is formed by appropriate material removing processes such as, e.g., etching, in particular anisotropic etching, chemical etching, dry etching, wet etching, in particular anisotropic dry or wet etching, reactive ion etching, mechanical machining, e.g. milling, cutting, etc., or other techniques known in the art of microstructuring.

The device carrier 110 may also comprise or be made of a semiconductor material. By way of example, both the lid 150 and the device carrier 110, may be made of the same semiconductor material, e.g. the lid 150 and/or the device carrier 110 may comprise or be made of silicon. In particular, the device carrier 110 may e.g. be a silicon chip and the lid 150 may e.g. be a (recessed) silicon chip.

By way of example, the device carrier 110 and/or the lid 150 may comprise or be made of crystalline silicon or of polycrystalline silicon. More specifically, the device carrier 110 may e.g. be a bulk semiconductor part. It is also possible that the device carrier 110 may comprise or be made of other types of carriers such as, e.g., a leadframe, a PCB or a metal bonded ceramic substrate as mentioned above.

In case the device carrier 110 comprises or is made of crystalline silicon or of polycrystalline silicon, it may also possible that the lid 150 may comprise or be made of other types of materials, e.g. insulating materials such as plastics mold materials, etc.

The semiconductor chip 130 may be mounted on the upper surface 110a of the device carrier 110. By way of example, the upper surface 110a of the device carrier 110 may be planar, resulting in that a lower main face 130a of the semiconductor chip 130 and the bottom surface 152a of the side wall 152 may extend essentially in the same plane.

The dimensions of the semiconductor device 100 may vary over wide ranges. In the following X and Y denote lateral directions while Z refers to a direction normal to the upper surface 110a of the device carrier 110. By way of example, the recess 151 may have a depth D measured in direction Z between the bottom surface 152a of the side wall and an inner surface 151a of the recess 151 equal or greater than 50 μm, 80 μm, 200 μm, 500 μm, 1000 μm, 2000 μm. On the other hand, the depth D may be equal or less than 2000 μm, 1000 μm, 500 μm, 200 μm, 80 μm, 50 μm. The depth D of the lid 151 may depend from the thickness Ts of the semiconductor chip 130 and may e.g. be larger than Ts.

A thickness of the lid 150 above the recess 151 in direction Z is denoted by Tl. Tl may be equal or greater than 200 μm, 350 μm, 500 μm, 1000 μm. Further, Tl may be equal or less than 2000 μm, 1000 μm, 500 μm, 350 μm, 200 μm.

The total height of the lid 150 in direction Z is denoted by H. H may be equal, greater or less than any of the aforementioned values of D and Tl, when added to H=D+Tl.

The semiconductor chip 130 may have a lateral dimension or width denoted by Ws. Ws may be equal or greater than 1 mm, 2 mm, 5 mm, 10 mm. Further, Ws may be equal or less than 10 mm, 5 mm, 2 mm, 1 mm. Ws may e.g. be measured in direction X or Y.

The width of the semiconductor device 100 may be defined by the maximum lateral dimension of the semiconductor device 100 and is denoted by Wd. Wd may either correspond to the maximum lateral dimension of the device carrier 110 or to the maximum lateral dimension of the lid 150. As depicted by way of example in FIG. 1, the lateral dimension of the device carrier 110 and the lid 150 in one (e.g. X) or two (e.g. X,Y) lateral directions may also be equal. It will be explained in more detail further below that equal lateral dimensions of the lid 150 and the device carrier 110 in one or two lateral dimensions may be obtained in case that the semiconductor device 100 is cut out of a multi-device array (see FIG. 10B). Wd may be greater than 1.5 mm, 5 mm, 1 cm, 3 cm, 5 cm. Further, Wd may be less than 5 cm, 3 cm, 1 cm, 5 mm, 1.5 mm.

As will be explained in more detail in the following, the semiconductor device 100 may be designed to include variations and/or additional details as set out below. It is to be understood that all of the details explained by way of example in the following could be combined with the semiconductor device 100 if not expressively stated to the contrary or impossible due to technical restrictions.

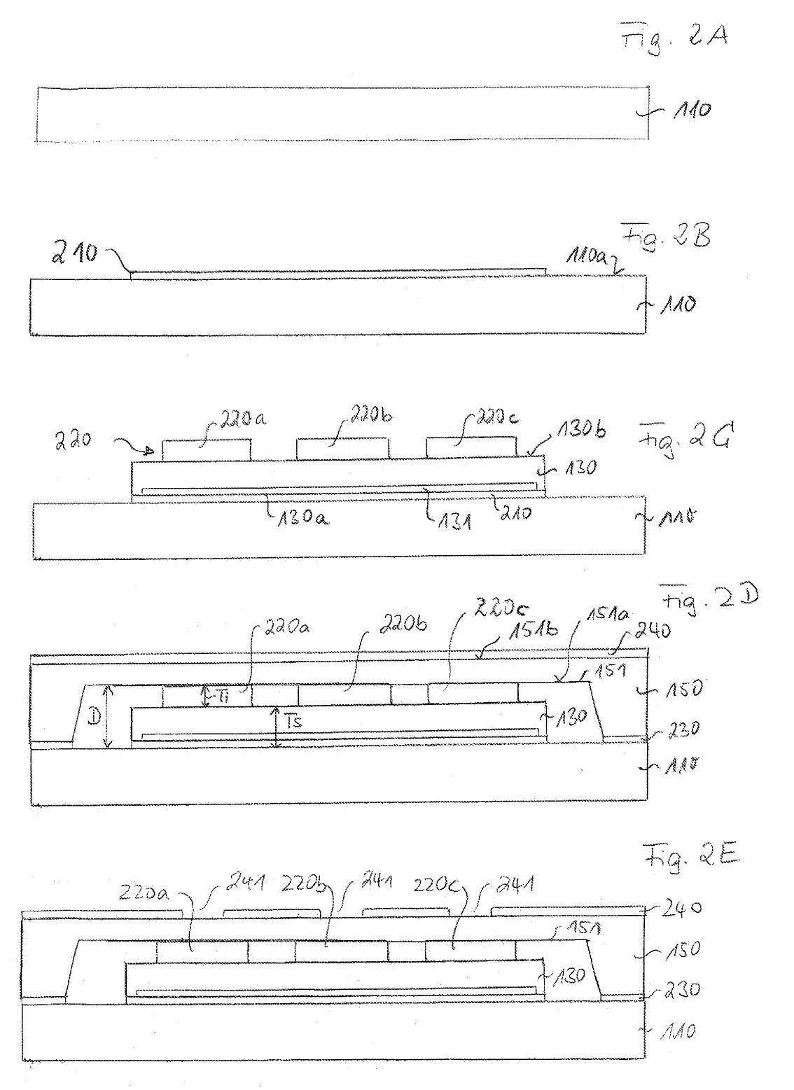

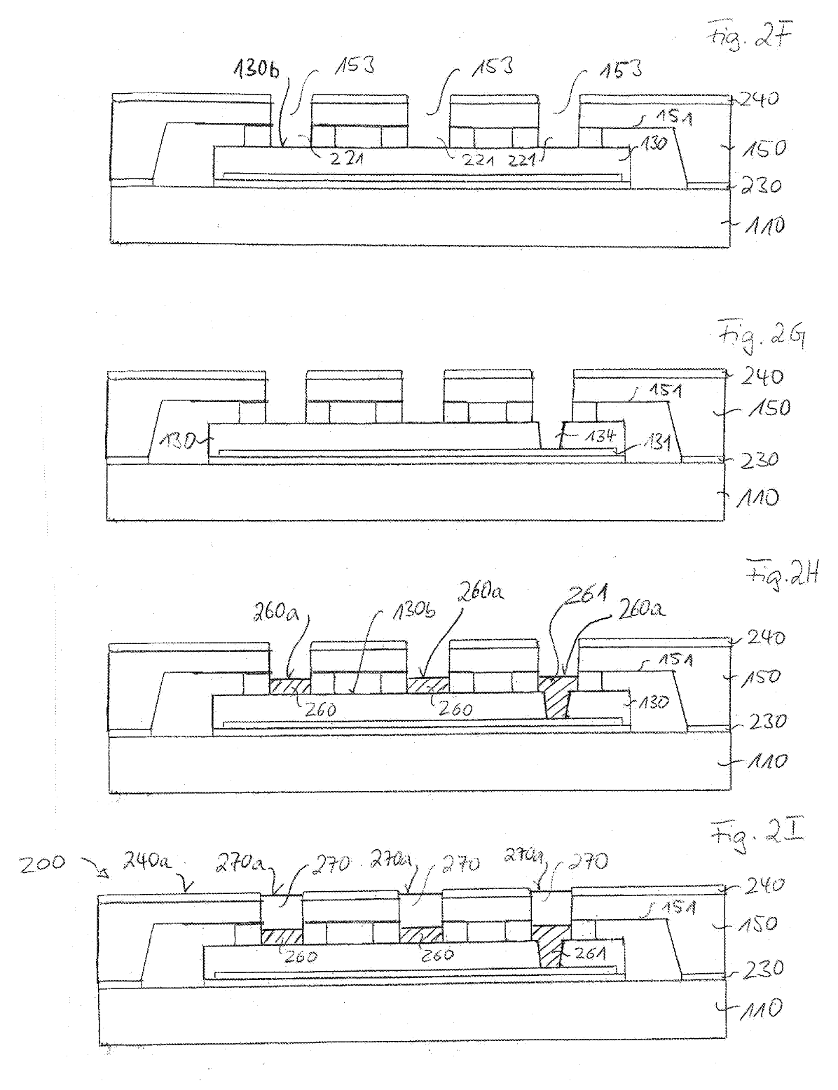

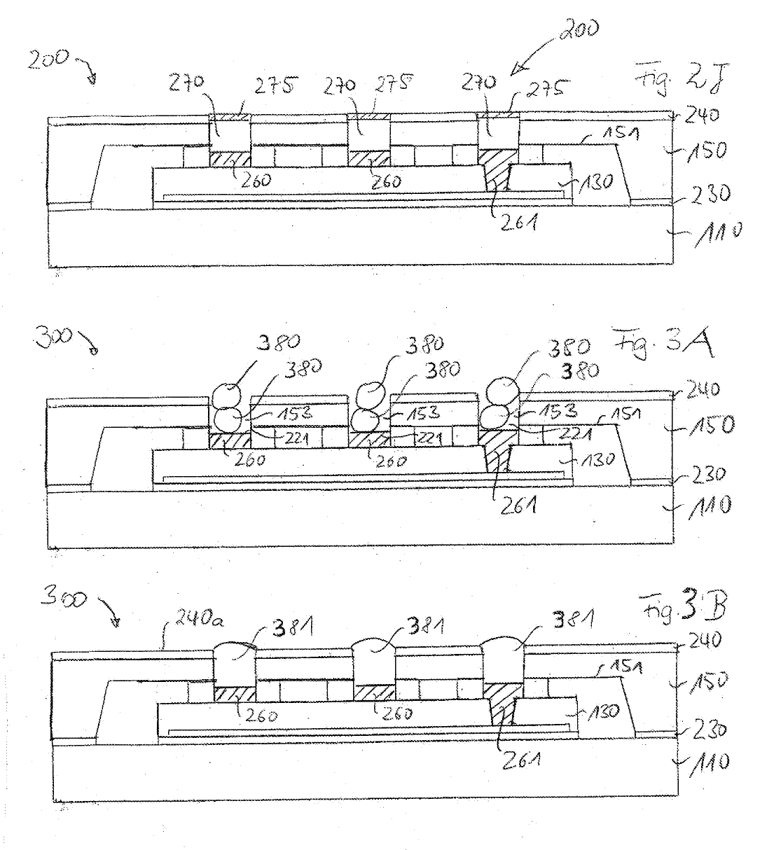

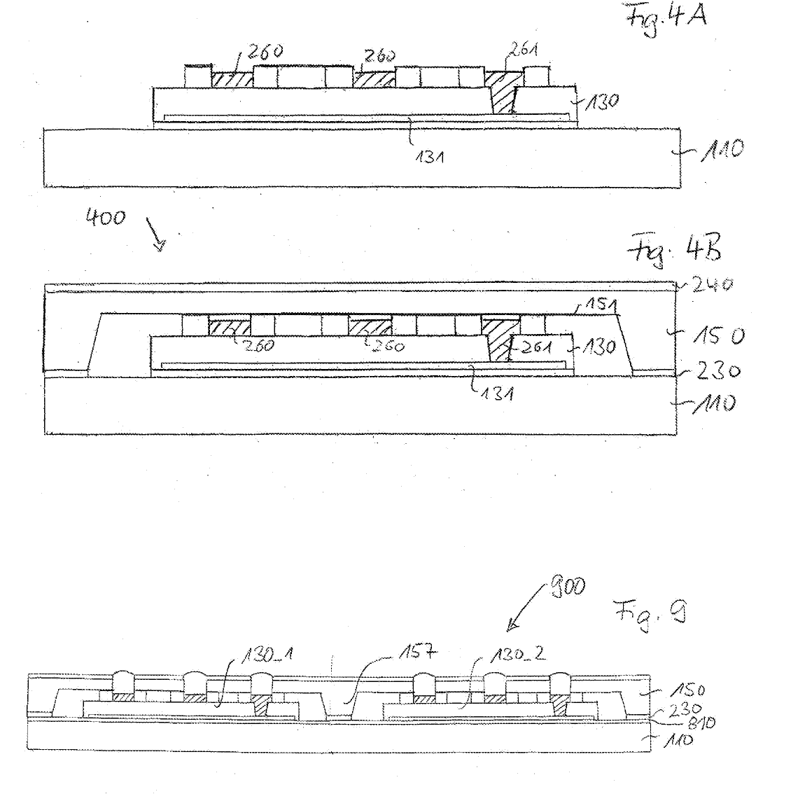

FIGS. 2A-2J illustrate process stages of an exemplary method of producing a semiconductor device 200. It is to be noted that the stages of production illustrated in FIGS. 2A-2J may be understood as simplifications, since further acts may be used which are not depicted in these figures. On the other hand, some of the acts illustrated in FIGS. 2A-2J may be omitted or substituted by other process acts. In particular, some possible variations are explained further below in conjunction with embodiments illustrated in FIGS. 3A-3B and 4A-4B. Moreover, the order of the described process stages may be modified or otherwise altered.

According to FIG. 2A, a device carrier 110 may be provided. In one implementation, the device carrier 110 may have the shape of a flat plate, e.g. a semiconductor chip, a plastic plate, a ceramic plate or a metal plate. As illustrated in FIG. 2B, a chip bonding layer 210 may be deposited on the upper surface 110a of the device carrier 110. The chip bonding layer 210 may comprise e.g. an adhesive, a solder material, metal particles, an organic paste containing metal particles, etc.

According to FIG. 2C, the semiconductor chip 130 is attached to the device carrier 110. The semiconductor chip 130 may be attached e.g. by adhesive bonding, soldering, diffusion soldering, sintering, etc. It is to be noted that the chip bonding layer 210 may be electrically conductive or may be electrically insulating. In an alternative implementation, a plurality of semiconductor chips 130 may be attached to the device carrier 110.

The semiconductor chip 130 may have a bottom electrode 131 exposed at the lower main face 130a of the semiconductor chip 130. By way of example, the semiconductor chip 130 may be configured as a vertical power semiconductor chip and may include power diode(s) or power transistor(s), for example power MOSFET(s), IGBT(s), JFET(s) or power bipolar transistor(s). In the case of a power MOSFET or a JFET the bottom electrode 131 may, e.g., be a drain electrode. In the case of a power bipolar transistor the bottom electrode 131 may, e.g., be a collector electrode, and in case of a power diode the bottom electrode may, e.g., be a cathode.

The semiconductor chip 130 has an upper main face 130b opposite to the lower main face 130a. A layer of insulating material 220 may be arranged over the upper main face 130b. The layer of insulating material 220 may be structured. By way of example, the layer of insulating material 220 may be structured to comprise a first portion 220a, a second portion 220b and a third portion 220c.

The layer of insulating material 220 may, e.g., comprise or be a hard passivation layer such as a silicon oxide, silicon nitride or a silicon oxide-nitride mixed layer. Further, the insulating layer 220 may comprise a polymer layer made of, e.g., a material to be directly or indirectly structured via photo lithography, e.g. a photoresist such as, e.g., SU8, a polyimide, a laminate, a printed polymer, BCB (benzocyclobutene), parylene, polynorbornene, epoxy or other organic materials.

According to FIG. 2D, a lid 150 is placed over the device carrier 110 and the semiconductor chip 130. The lid 150 has a recess 151 e.g. designed, dimensioned and manufactured as disclosed above in conjunction with FIG. 1. In order to avoid reiteration, reference is made to the corresponding description.

The lid 150 may be fixed to the device carrier 110 by a lid bonding layer 230. The lid bonding layer 230 may e.g. comprise an adhesive material or a solder material. In other implementations, e.g. if the device carrier 110 and the lid 150 both comprise or be made of a semiconductor material, e.g. silicon, the lid bonding layer 230 may e.g. be a semiconductor oxide bonding layer.

It is to be noted that the layer of insulating material 220 may be adapted to have a thickness Ti (in the Z direction, see FIG. 1) to support the inner surface 151a of the recess 151 of the lid 150. In other words, Ti=D−Ts, wherein Ti may be of the range of values defined by the ranges of values of D and Ts as disclosed above.

An outer surface 151b of the lid 150 may be covered by an insulating layer 240. By way of example, the insulating layer 240 may comprise a polymer layer made of, e.g., a material to be directly or indirectly structured via photo lithography, e.g. a photoresist such as, e.g., SU8, a polyimide, a laminate, a printed polymer, BCB (benzocyclobutene), parylene, polynorbornene, epoxy or other organic materials.

As shown in FIG. 2E, the insulating layer 240 may then be structured. The structuring may e.g. be performed by photolithographic patterning or by direct laser beam patterning. It is also possible that the insulating layer 240 is applied in a pre-structured design, e.g. by using printing or laminating techniques.

The structured insulating layer 240 may be used as a mask layer in order to remove semiconductor material from the lid 150 beneath openings 241 generated in the insulating layer 240 by the structuring process. More specifically, etching may be applied to the semiconductor material contained in the lid 150 through the openings 241. Conventional etching techniques such as, e.g., reactive ion etching, chemical etching, dry etching, wet etching, laser ablation, may be applied to the lid 150.

As shown in FIG. 2F, contact holes 153 passing through the thickness of the lid 150 may be produced. Further, the etching process or, e.g., another process for removing material may be applied to generate through-holes 221 passing through the layer of insulating material 220, or, more specifically, e.g. through the portions 220a, 220b, 220c thereof. As illustrated in FIG. 2F, the contact holes 153 passing through the lid 150 and the through-holes 241 aligned to the contact holes 153 and passing through the layer of insulating material 220 may e.g. expose portions of the upper main face 130b of the semiconductor chip 130. Generally speaking, the lid 150 has at least one opening (e.g. contact hole 153) through which the semiconductor chip 130, e.g. a portion of the upper main face 130b thereof, is exposed.

The inner surfaces of the contact holes 153 and/or the through-holes 221 may be at least partially covered by an insulating material layer (not shown). Depending on the manufacturing process, the insulating material layer may e. g. cover only the sidewall of the contact holes 153 of the lid 150. This may e.g. be the case when the insulating material layer (not shown) is applied before the through-holes 221 through the layer of insulating material 220 are etched (such exemplary two step hole formation process is not shown in FIG. 2F). According to other embodiments the insulating material layer (not shown) covering the sidewall of the contact holes 153 and/or the through-holes 221 reaches to the upper main surface 130b of the semiconductor chip 130. By way of example, the insulating material layer may be made of or may comprise, e.g., silicon oxide, silicon nitride, silicon oxinitride, a polymer layer made of, e.g. SU8, a polyimide, a laminate, a printed polymer, BCB (benzocyclobutene), epoxy or other organic materials.

Further, as exemplified by FIG. 2G, a through silicon via (TSV) 134 may be generated in alignment of, e.g., one or more of the contact holes 153 and through-holes 221. The TSV 134 may expose the bottom electrode 131 of the semiconductor chip 130.

Further, the sidewalls of the TSV 134 may be covered by an insulating material and/or a barrier material (not shown). The insulating material may be made of or comprise, e. g., silicon nitride, silicon oxide, silicon oxinitride, a polymer like, e. g., SU8, polyimide etc. The barrier material may be made of or comprise, e. g., TiN, TaN, TiW etc.

As shown in FIG. 2H, electrical contacts 260 may then be applied to the upper main face 130b of the semiconductor chip 130. The electrical contacts 260 may be applied by depositing metal through the lid openings (e.g. contact holes 153) and, optionally, through-holes 221 onto the upper main face 130b of the semiconductor chip 130. The metal of the electrical contacts 260 may be deposited on top electrodes (not shown) situated at the upper main face 130b of the semiconductor chip 130. These top electrodes (not shown) may either be pre-fabricated e.g. during previous semiconductor wafer processing or may be generated after lid placement by processing the upper main face 130b of the semiconductor chip 130 through the contact holes 153 and through-holes 221 before depositing the metal of the electrical contacts.

By way of example, the top chip electrodes (not shown) lying beneath the electrical contacts 260 and being electrically connected thereto may be a source electrode and a gate electrode in case the semiconductor chip 130 is e.g. a power MOSFET or a JFET. In case the semiconductor chip 130 is an IGBT, the top chip electrodes may e.g. be an emitter electrode and a gate electrode. In case the semiconductor chip 130 is a bipolar transistor, the top chip electrodes may be an emitter electrode and a base electrode. In case the semiconductor chip 130 is a power diode, a top chip electrode may be the anode of the diode.

It is to be noted that for all power applications exemplified above, voltages up to 5, 50, 100, 500 or 1000 V or even higher may be applied between top and bottom chip electrodes.

Further referring to FIG. 2H, the electrically conducting TSV 134 may be generated by depositing metal 261 through contact hole 153 and, e.g., through-hole 221 into TSV 134. The generation of the electrically conducting TSV 134 may e.g. be performed within the same metal depositing act used for generating the electrical contacts 260. That is, electrical contact 260 formation and TSV 134 filling may be performed by using e.g. the same metal material 261 and the same metal deposition method.

Then, external terminals of the semiconductor device 200 may be formed. There are many possibilities to generate external terminals. By way of example, as illustrated in FIG. 2I, the contact holes 153 and, e.g., the through-holes 221 may be filled by a conducting material 270.

A process of electroless plating may be used to fill the contact holes 153 and the through-holes 221 by conducting material 270. In electroless plating, also referred to as chemical plating in the art, first, a seed layer (not shown) may be generated onto the top surface of the electrical contacts 260. The seed layer may, e.g., be made of palladium or another suitable material. It is also possible to omit the application of a seed layer in case the surface of the electrical contacts 260 may act as seed layers themselves. By way of example, the top surfaces of the electrical contacts 260 may be irradiated by a laser beam for activating the irradiated surfaces.

Then, as shown in FIG. 2I, a metal (typically nickel or copper) may be deposited onto the seed layer (not shown) or the activated surfaces of the electrical contacts 260. The metal of the conducting material 270 may be applied by electroless plating, i.e. by emerging the semiconductor device into an electroless chemical bath for metal deposition. The upper surface 270a of the conducting material 270 may be lower (concave) or higher (convex) than the upper surface 240a of the insulating layer 240. Subsequently, a temperature step at about 300° C. to 400° C. may be applied in order to decrease the specific resistance of deposited metal, e.g. copper or nickel.

The plating may take place by starting from the top surfaces 260a of the electrical contacts 260 only or the plating may start from the top surfaces 260a of the electrical contacts 260 and the sidewalls of the contact holes 153. E.g. in this case, a void may remain in the conducting material 270 which may either be buried inside the conducting material 270 or may reach the upper surface 270a of the conducting material 270.

A thin layer 275 of an electrically conducting material, e.g. a noble metal such as, e.g., gold or silver, may optionally be applied onto the top of the conducting material 270 as shown in FIG. 2J. The upper surface of the conducting material 270 or, if a noble metal layer 275 is applied, of the noble metal layer 275 may be used as an external terminal for electrically connecting the semiconductor device 200 to an external application such as, e.g., to an application board.

Many other possibilities for applying external terminals to the semiconductor device 200 are feasible. By way of example, printing methods such as, e.g., screen printing, stencil printing or ink-jet printing, or dispensing may be used. Further, as shown in FIGS. 3A and 3B, solder may be used as a conducting material 270 and/or for generating the electrical contacts 260.

More specifically FIG. 3A illustrates a semiconductor device 300 which may be identical to semiconductor device 200 shown in FIG. 2J except that one or more solder deposits 380, e.g. solder balls or solder paste (not shown), may be filled into the contact holes 153 and, e.g., into the through-holes 221. The solder deposits 380 are then subjected to a thermo-process to reflow the solder deposits 380. This reflow act may result in that the contact holes 153 and, e.g., the through-holes 221 are completely filled by solder material 381. The upper exposed surface of the solder material 381 may protrude over a plane defined by the upper surface 240a of the insulating layer 240 (or, more generally, the upper surface of the semiconductor device 200). The solder material 381 may be used in a subsequent reflow process to connect the semiconductor device 200 to an external application, e.g. a customer's application board.

It is to be noted that in the processes exemplified by FIGS. 2A-3B, virtually all method acts including, e.g., the TSV formation, the top chip electrode formation, the electrical contact 260 generation, the contact hole 153 filling, etc., may e.g. be performed from a top direction, i.e. a direction facing the outer surface 151b of the lid 150 (e.g. in Z direction). Further, all of these processes may, e.g., be performed after the lid 150 is fixedly secured to the device carrier 110 via the lid bonding layer 230. However, it is also possible that one, more or all the mentioned processes may be performed prior to the mounting of the lid 150 onto the device carrier 110. In particular, the top chip electrodes (not shown) may be pre-fabricated at wafer or chip level, the TSV 134 may be pre-fabricated at wafer or chip level, the electrical contacts 260 may be pre-fabricated at chip or wafer level and the contact holes 153 passing through the lid 150 may be pre-fabricated at chip or wafer level e.g. before the lid 150 is placed on top of the device carrier 110 and the semiconductor chip 130 attached thereto. It is to be noted that, if the lid 150 is attached to the device carrier 110 after one or more of the processes mentioned above, any elevated temperature which might be needed to bond the lid 150 to the device carrier 110 may not exceed a critical temperature which would jeopardize the structures generated during previous process acts. On the other hand, a reflow process, as shown e.g. in FIG. 3B, has to be performed at a temperature below a critical temperature at which the lid 150 would detach from the device carrier 110.

FIGS. 4A-4B illustrate method acts of a process to manufacture a semiconductor device 400. The process may be similar to the process described above in conjunction with FIGS. 2A-3B. However, in contrast to FIG. 2D, the TSV 134 and the electrical contacts 260 are fabricated before the lid 150 is attached, e.g. glued, solder bonded or oxide bonded, to the device carrier 110, see FIG. 4B.

Then, similar to the process illustrated in FIG. 2E, the insulating layer 240 shown in FIG. 4B may be structured for generating opening 241 vertically aligned to the electrical contacts 260. Further, contact holes 153 may be generated, e.g., by using the structured insulating layer 240 as a mask layer, see FIG. 2F. As to the further processing, in order to avoid reiteration, reference is made by way of example to the processes described above in conjunction with FIGS. 2H-3B.

As e.g. shown in FIG. 5, in one embodiment of a semiconductor device 500, the lid 150 may be designed to be self supporting, i.e. the lid 150 is only supported by the device carrier 110 via the side wall 152 of the lid 150.

FIG. 6 illustrates additional and/or alternative support structures which may be used to support the lid 150. A semiconductor device 600 may comprise a first support structure for supporting the inner surface 151a of the lid 150 which includes the semiconductor chip 130. In addition, this first support structure may further include the layer of insulating material 220 (see FIGS. 2A-4B), and/or an integral post 222 thereof projecting over an upper surface of the layer of insulating material 220, and/or an integral protrusion 155 or 156 of the lid 150 at the inner surface 151a of the lid 150. The integral protrusion 155 may be supported, e.g., by the layer of insulating material 220 and the integral protrusion 156 may be supported directly by the semiconductor chip 130. Further, the inner surface 151a of the lid 150 may be supported by a second support structure comprising, e.g., a stand-off part 157 integrally formed of the lid 150 and extending within the outline of the recess 151 between the lid 150 and the device carrier 110 of the semiconductor device 600.

FIG. 7 illustrates a semiconductor device 700 comprising stand-off parts 710 extending between the inner surface 151a of the recess 151 of the lid 150 and the device carrier 110. These stand-off parts 710 may be fabricated on the device carrier 110 before the lid 150 is placed over the semiconductor chip 130 and the device carrier 110. By way of example, the stand-off parts 710 may be generated by deposition of metal structures or structures of organic materials like duromers, e.g. columns, of appropriate height, e.g. a height corresponding to the depths D of the recess 151 (e.g. plus the thickness of the lid bonding layer 230). The stand-off parts 710 may also be fabricated by semiconductor structuring methods, e.g. if the device carrier 110 is a semiconductor chip.

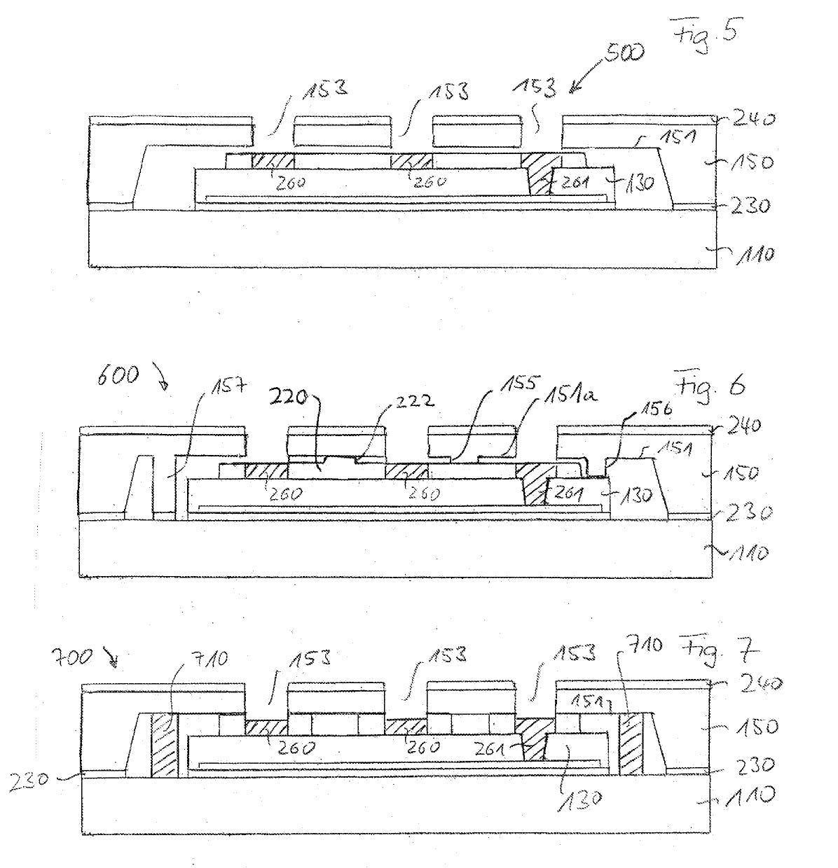

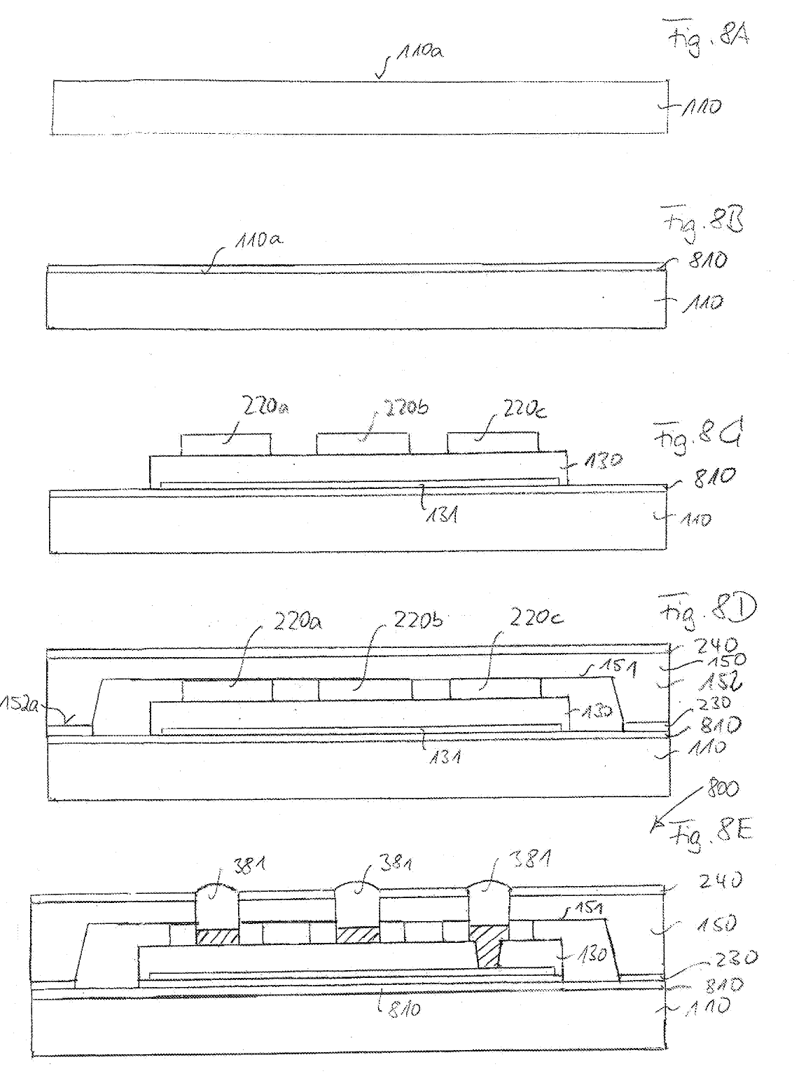

FIGS. 8A-8E illustrate process stages of a method of manufacturing a semiconductor device 800. The semiconductor device 800 may be similar to the semiconductor device 300, and reference is made to the above description in order to avoid reiteration. However, in contrast to semiconductor device 300, the semiconductor device 800 comprises a device carrier insulating layer 810. The device carrier insulating layer 810 may extend over the upper surface 110a of the device carrier 110. The device carrier insulating layer 810 may be an unstructured layer which completely covers the upper surface 110a of the device carrier 110. In other embodiments, e.g. in particular in embodiments of a multi-chip semiconductor device, the device carrier insulating layer 810 may be a structured layer. In this case at least one semiconductor chip 130 is attached onto the device carrier insulating layer 810 in order to be electrically insulated from the device carrier 110 (and, e.g., from the other semiconductor chip, if any).

Further, it is also possible that the device carrier insulating layer 810 is buried in the device carrier 110. In this case, the semiconductor chip 130 may e.g. be attached to an e.g. insular metal structure on the buried insulating layer 810.

More specifically, FIG. 8A illustrates providing a device carrier 110 as already explained in conjunction with FIG. 2A. FIG. 8B illustrates coating the upper surface 110a of the device carrier 110 with the device carrier insulating layer 810. By way of example, the device carrier insulating layer 810 may be a hard passivation layer such as, e.g., a silicon oxide layer, a silicon nitride layer or a silicon oxide-nitride mixed layer. Such hard passivation layers may be generated at wafer level at the upper surface 110a of the device carrier 110 in case the device carrier 110 is a semiconductor carrier, e.g. a silicon carrier of e.g. polycrystalline or crystalline silicon.

In other implementations the device carrier insulating layer 810 may be made of a polyimide foil, a material to be directly or indirectly structured via photo lithography, e.g. a photoresist such as, e.g., SU8, BCB (benzocyclobutene), parylene, polynorbornene, epoxy or other organic materials.

As shown in FIG. 8C, the semiconductor chip 130 is attached onto the device carrier insulating layer 110. Reference is made to the corresponding description in relation to FIG. 2C for the sake of brevity.

As shown in FIG. 8D, the lid 150 is placed onto the device carrier 110 and bonded to the device carrier 110 via a lid bonding layer 230. Reference is made to the corresponding description of FIG. 2D to avoid reiteration. The lid 150 may either be bonded via e.g. the lid bonding layer 230 onto the device carrier insulating layer 810, as shown in FIG. 8D, or the device carrier insulating layer 810 may be cut out to allow the bottom surface 152a of the side wall 152 of the lid 150 to be bonded via e.g. the lid bonding layer 230 to the device carrier 110.

In the following, processes such as e.g. exemplified in FIGS. 2E-3B may be carried out. By way of example, FIG. 8E illustrates a semiconductor device 800 produced in line with the method acts shown in FIGS. 2E-2H and 3A-3B. Reference is made to the corresponding disclosure in order to avoid reiteration. Without saying, other method acts such as, e.g., explained above in conjunction with FIGS. 2I-2J and/or FIGS. 4A-4B, may also be applied.

FIG. 9 illustrates a cross-sectional view of an exemplary multi-chip semiconductor device 900. The multi-chip semiconductor device 900 comprises a device carrier 110 on which a plurality of semiconductor chips 130_1 and 130_2 are mounted. Without loss of generality, in the following, two semiconductor chips 130_1, 130_2 may be provided in the multi-chip semiconductor device 900. Further, also without loss of generality, the two semiconductor chips 130_1, 130_2 may be mounted on a device carrier insulating layer 810 as described in conjunction with FIGS. 8A-8E. It is, however, also possible that one or all of the semiconductor chips 130_1, 130_2 are directly mounted on the upper surface 110a of the device carrier 110 via the chip bonding layer 210, see e.g. FIG. 2C and the corresponding disclosure.

The lid 150 shown in FIG. 9 may be identical to the lid 150 described above, with the exception that the recess 151 and the lateral dimensions of the lid 150 shown in FIG. 9 are large enough to accommodate a plurality of semiconductor chips 130_1, 130_2. By way of example, as mentioned earlier, the lid 150 may be equipped with an integrally formed stand-off 157 to support the lid 150 in a region between semiconductor chip 130_1 and semi-conductor chip 130_2. The multi-chip semiconductor device 900 and the semiconductor chips 130_1 and 130_2 may have the same features and may be fabricated by the same processes as described before, including all variations described herein but not illustrated in FIG. 9.

FIGS. 10A and 10B illustrate a plate-like structure 110′ having an upper surface 110a′. The plate-like structure 110′ will be referred to as a multi-device carrier in the following, because the device carriers 110 are produced from the plate-like structure 110′ by separating the plate-like structure 110′ into single device carriers 110. The upper surface 110a′ of the multi-device carrier 110′ may be partially or fully coated with a device carrier insulating layer 810, which is not shown in FIGS. 10A and 10B.

In the following, without loss of generality, the multi-device carrier 110′ may be assumed to be a semiconductor wafer, e.g., a silicon wafer. However, in general, multi-device carrier 110′ may be made of any of the aforementioned materials used as a device carrier 110. The only limitation is that the multi-device carrier 110′ has a lateral dimension which is much greater than the lateral dimension of the device carrier 110 in order to provide a plurality of device carriers 110 (e.g. semiconductor chips) when being diced. By way of example, the multi-device carrier 110′ may e.g. be disc-shaped having a diameter of e.g. 200 or 300 mm, or may have any other shape such as a polygonal shape with the same or other lateral dimensions.

In a following act, which is not shown in FIG. 10A, semiconductor chips 130 are mounted on the multi-device carrier (e.g. semiconductor wafer) 110′. The semiconductor chips 130 are, e.g., attached onto the upper surface 110a′ of the multi-device carrier 110′ or onto the device carrier insulating layer 810 (not shown) covering the multi-device carrier 110′. Reference is made to the corresponding disclosure of embodiments described herein. The semiconductor chips 130 may be placed in a spaced-apart relationship onto the multi-device carrier 110′.

FIG. 10B shows an array of semiconductor devices 1000. Lids 150 each having a recess 151 are placed over the multi-device carrier 110′ and the semiconductor chips 130 mounted thereon to accommodated the semiconductor chips 130 in the plurality of recesses. Fixing the lids 150 to the multi-device carrier 110′ may be accomplished e.g. by a thermo process as disclosed above.

More specifically, the array of semiconductor devices 1000 may e.g. comprise a lid bonding layer 230 (not shown) arranged between the multi-device carrier 110′ and the lids 150. The lid bonding layer 230 may be structured to underlay the side walls 152 of the lids 150 and may be configured to fix the multi-device carrier 110′ and the lids 150 together.

The lids 150 may be arranged in one or more continuos arrays 1050 of lids 150 which may have been integrally cut from a semiconductor wafer (referred to as a “lid wafer” in the following) used to produce the lids 150. That is, a plurality of recesses 151 may have been formed as a recess pattern in the semiconductor material of the lid wafer (not shown), and the lid wafer is then separated to obtain the one or more continuos arrays 1050 of lids 150. In FIG. 10B, by way of example, arrays 1050 of lids 150 are exemplified by rows of lids 150. For ease of perception, the locations of the recesses 151 of the lids 150 are indicated in FIG. 10B by rectangular lines.

It is to be noted that arrays 1050 of lids 150 other than rows may be used to place a plurality of lids 150 in a batch process onto the multi-device carrier 110′. By way of example, the entire lid wafer (not shown) in which the lids 150 have been produced may be used as an array 1050 of lids 150 which is placed onto and attached to the multi-device carrier 110′. In other embodiments, two dimensional rectangular arrays of lids 150 may be used, e.g. n×m arrays containing n lids in X direction and m lids in Y direction, with n, m being integers. It is also possible that single lids 150 are placed onto the multi-device carrier 110′ in a spaced-apart relationship. Placement and attachment of single lids 150 or arrays 1050 of lids 150 may e.g. be performed in a parallel process (batch process) or in a sequential manner (e.g. pick-and-place-process).

All processes described herein before may then be performed on wafer level as exemplified in FIG. 10B. Here, wafer level means that the multi-device carrier 110′ (e.g. semiconductor wafer) is still integral, i.e. not separated into single semiconductor devices 100, 200, 300, 400, 500, 600, 700, 800, 900. When processed on wafer level, single lids 150, arrays 1050 of integral lids 150 such as, e.g., rows as shown in FIG. 10B or the integral “lid wafer” may be subjected to wafer level processing. By way of example, the processes of e.g. insulating layer 240 application and/or structuring, TSV 134 formation, top chip electrode formation, electrical contact 260 generation, contact hole 153 filling, etc., may be performed on wafer level, either on single lids 150 or on lid array 1050 structures.

FIG. 10B further illustrates an act of singulating the multi-device carrier 110′ into a plurality of semiconductor devices 100, 200, 300, 400, 500, 600, 700, 800, 900. Singulation may be performed by using a dicing technique such as, e.g., blade dicing (sawing), laser dicing, etching, etc. The semiconductor devices 100, 200, 300, 400, 500, 600, 700, 800, 900 are singulated along dicing streets which are depicted in FIG. 10B by dashed lines. Byway of example, semiconductor devices 100, 200, 300, 400, 500, 600, 700, 800, 900 may be produced by using a mesh-like dicing street pattern as shown in FIG. 10B.

In general, the dicing streets extend through the multi-device carrier 110′. Further, the dicing streets may extend through the semiconductor material of the array(s) 1050 of lids 150, i.e. the entire lid wafer or a part thereof. The at least one integral array 1050 of lids 150 may thus be singulated into single lids 150 when separating the multi-device carrier 110′ into a plurality of semiconductor devices 100, 200, 300, 400, 500, 600, 700, 800, 900.

By way of example, if rows of lids 150 are used as shown in FIG. 10B, all dicing streets oriented in a first direction (in FIG. 10B in Y direction) run both through the semiconductor material of the arrays 1050 of lids 150 and the (e.g. semiconductor) material of the multi-device carrier 110′, while the dicing streets oriented in a second direction (in FIG. 10B in X direction) run through the semiconductor material of the multi-device carrier 110′ but may extend between adjacent rows of lids 150, that is e.g. without cutting the semiconductor material of the lids 150.

Returning to FIGS. 1-9, all semiconductor devices 100, 200, 300, 400, 500, 600, 700, 800, 900 exemplified in these figures show to have peripheral side faces of the device carrier 110 which are flush with peripheral side faces of the lid 150. This design of flush or coplanar side faces of the lid 150 and the device carrier 110 may e.g. be produced by dicing streets similar to the dicing streets shown in FIG. 10B running in Y direction.

Although specific embodiments have been illustrated and described herein, it will be appreciated by those of ordinary skill in the art that a variety of alternate and/or equivalent implementations may be substituted for the specific embodiments shown and described without departing from the scope of the present invention. By way of example, in all embodiments disclosed herein at least one of the device carrier and the lid is made of or comprises a semiconductor material, e.g. a bulk semiconductor part. This application is intended to cover any adaptations or variations of the specific embodiments discussed herein. Therefore, it is intended that this invention be limited only by the claims and the equivalents thereof.

1. An apparatus, comprising:
a device carrier;
a semiconductor chip attached to the device carrier; and
a lid having a recess, wherein the lid is attached to the device carrier, the semiconductor chip is accommodated in the recess and the lid comprises a semiconductor material.

2. The apparatus of claim 1, wherein the recess is formed in the semiconductor material.

3. The apparatus of claim 1, wherein the device carrier comprises a material which is selected of the group consisting of a semiconductor material, a printed circuit board, a leadframe, and a metal bonded ceramics.

4. The apparatus of claim 1, wherein the device carrier comprises an electrically insulating layer.

5. The apparatus of claim 4, wherein the semiconductor chip is attached to the electrically insulating layer.

6. The apparatus of claim 4, wherein the insulating layer is buried in the device carrier.

7. The apparatus of claim 1, wherein the semiconductor chip is a power semiconductor chip.

8. The apparatus of claim 1, wherein the lid has at least one opening through which a chip electrode is electrically connected to an external contact terminal of the semiconductor device, wherein the external contact terminal is located at an outer surface of the lid.

9. The apparatus of claim 8, wherein all external contact terminals of the semiconductor device are located at the outer surface of the lid.

10. The apparatus of claim 1, wherein an inner surface of the lid is supported by a first support structure which includes the semiconductor chip.

11. The apparatus of claim 1, wherein an inner surface of the lid is supported by a second support structure which is a stand-off part integrally formed of the lid.

12. An apparatus, comprising:
a multi-device carrier;
a plurality of semiconductor chips attached to the multi-device carrier; and
an array of lids having a plurality of recesses, wherein the array of lids is attached to the multi-device carrier, the plurality of semiconductor chips is accommodated in the plurality of recesses and the array of lids comprises a semiconductor material.

13. The apparatus of claim 12, wherein the array of lids comprises a semiconductor wafer.

14. The apparatus of claim 12, wherein the plurality of recesses is formed as a recess pattern in the semiconductor material.

15. The apparatus of claim 12, wherein the multi-device carrier comprises a semiconductor wafer.

16. An apparatus, comprising:
a device carrier which comprises a semiconductor material;
a semiconductor chip attached to the device carrier; and
a lid having a recess, wherein the lid is attached to the device carrier and the semiconductor chip is accommodated in the recess.

17. A method, comprising:
providing a device carrier;
attaching a semiconductor chip to the device carrier;
forming a lid having a recess, wherein the lid comprises a semiconductor material; and
attaching the lid to the device carrier, wherein the semiconductor chip is accommodated in the recess.

18. The method of claim 17, further comprising:
forming at least one opening in the lid, wherein the opening is aligned to a chip electrode;
filling the opening at least partially with a conductive material to generate an external contact terminal of the semiconductor device.

19. The method of claim 15, further comprising:
forming at least one opening in the lid;
forming a chip electrode on the semiconductor chip by processing the semiconductor chip through the opening; and
filling the opening with a conductive material to generate an external contact terminal of the semiconductor device.

20. A method, comprising:
providing a multi-device carrier;
attaching a plurality of semiconductor chips to the multi-device carrier;
attaching a plurality of lids comprising a semiconductor material to the multi-device carrier, wherein a plurality of recesses is formed in the semiconductor material and the plurality of semiconductor chips is accommodated in the plurality of recesses; and thereafter
separating the multi-device carrier into a plurality of semiconductor devices.

21. The method of claim 20, wherein attaching the plurality of lids to the multi-device carrier comprises attaching at least one integral array of lids to the multi-device carrier.

22. The method of claim 21, further comprising:
processing a semiconductor wafer to form a pattern of recesses in the semiconductor wafer; and
separating the semiconductor wafer to obtain the at least one integral array of lids.

23. The method of claim 21, further comprising:
separating the at least one integral array of lids into single lids when separating the multi-device carrier into a plurality of semiconductor devices.

24. The method of claim 20, further comprising:
forming a plurality of openings in the plurality of lids, wherein the plurality of openings is aligned to a plurality of chip electrode; and
filling the plurality of openings with a conductive material to generate a plurality of external contact terminals of the semiconductor device.

25. The method of claim 20, further comprising:
forming a plurality of openings in the plurality of lids;
forming a plurality of chip electrodes on the plurality of semiconductor chips by processing the plurality of semiconductor chips through the plurality of openings; and
filling the plurality of openings with a conductive material to generate a plurality of external contact terminals of the semiconductor device.
